(19) United States
(12) Patent Application Publication
(10) Pub. No.: US 2025/0160062 A1
(43) Pub. Date: May 15, 2025

(54) LIGHT-EMITTING DIODE EPITAXIAL STRUCTURE AND LIGHT-EMITTING DIODE

(71) Applicant: HUAIAN AUCKSUN OPTOELECTRONICS TECHNOLOGY CO., LTD, Huaian, Jiangsu (CN)

(72) Inventors: Licheng Huang, Huaian, Jiangsu (CN); Changwei Song, Huaian, Jiangsu (CN); Yuan Guo, Huaian, Jiangsu (CN); Chih-Ching Cheng, Huaian, Jiangsu (CN); Ling Lu, Huaian, Jiangsu (CN)

(21) Appl. No.: 18/725,284

(22) PCT Filed: Nov. 8, 2022
(86) PCT No.: PCT/CN2022/130718

§ 371 Date: Jun. 28, 2024

(30) Foreign Application Priority Data
Dec. 30, 2021 (CN) 202111655093.8
Aug. 23, 2022 (CN) 202211012734.2

(51) Int. Cl. H10H 20/81; H10H 20/812; H10H 20/816; H10H 20/825

(52) U.S. Cl. CPC H10H 20/8215; H10H 20/812; H10H 20/8162; H10H 20/825

(57) ABSTRACT

A light-emitting diode epitaxial structure and a light-emitting diode are provided. The light-emitting diode epitaxial structure is provided with an Mg modulation layer disposed between a multi-quantum well light-emitting layer and a first hole injection layer. The average impurity doping concentration of the Mg modulation layer is A, the average impurity doping concentration of the first hole injection layer is B, and the average impurity doping concentration of an electron blocking layer is C, where B>A>C.

### CROSS-REFERENCE TO RELATED APPLICATION

The present disclosure claims the priority to the Chinese patent application filed with the China National Intellectual Property Administration on Dec. 30, 2021 with the filing No. 202111655093.8 and entitled “LIGHT-EMITTING DIODE AND PREPARATION METHOD THEREFOR”, and the Chinese patent application filed with the China National Intellectual Property Administration on Aug. 23, 2022 with the filing No. 202211012734.2 and entitled “EPITAXIAL STRUCTURE OF LIGHT-EMITTING DIODE AND LIGHT-EMITTING DIODE”, all the contents of which are incorporated herein by reference in entirety.

### TECHNICAL FIELD

The present disclosure relates to the technical field of semiconductors, and specifically to an epitaxial structure of a light-emitting diode and a light-emitting diode.

### BACKGROUND ART

A light-emitting diode (LED for short) is a light-emitting device, and is widely applied in illumination, display devices, medical devices and other fields due to the advantages such as energy conservation, environmental protection, small size and good color-rendering property and response speed.

A structure of the light-emitting diode in the prior art includes: a substrate, and an N-type semiconductor layer, a multi-quantum well layer, an electron-blocking layer and a P-type semiconductor layer which are sequentially provided on the substrate. In the above, the P-type semiconductor layer is usually doped with P-type impurities, and concentration setting of the P-type impurities may affect effects of electron-blocking and hole-injecting.

However, a concentration of doping impurity is not limited at present.

In view of this, the present disclosure is specifically proposed.

### SUMMARY

A first objective of the present disclosure is to provide an epitaxial structure of a light-emitting diode, in which epitaxial structure, by providing an Mg modulation layer between a multi-quantum well light-emitting layer and a P-type semiconductor layer, and defining a doping concentration of impurities, better effects of electron-blocking and hole injecting can be generated.

In order to realize the above objectives of the present disclosure, the following technical solutions are particularly adopted.

An epitaxial structure of a light-emitting diode provided by the present disclosure includes: a substrate; and an N-type semiconductor layer, a multi-quantum well light-emitting layer, and a P-type semiconductor layer which are sequentially provided on an upper surface of the substrate, wherein the P-type semiconductor layer includes a first hole-injecting layer, an electron-blocking layer and a second hole-injecting layer, wherein the P-type semiconductor layer is doped therein with a P-type impurity Mg, and the P-type impurity Mg has different doping concentrations or concentration variations in different sub-layers of the P-type semiconductor layer;
an Mg modulation layer is provided between the multi-quantum well light-emitting layer and the first hole-injecting layer;
an average doping concentration of impurity in the Mg modulation layer is A, an average doping concentration of impurity in the first hole-injecting layer is B, and an average doping concentration of impurity in the electron-blocking layer is C, where
B>A>C.

Preferably, a direction from the second hole-injecting layer to the substrate is defined as a first direction; and
in the first direction, a difference between a maximum value and a minimum value of the doping concentration of Mg in the Mg modulation layer is different from a difference between a maximum value and a minimum value of the doping concentration of Mg in the first hole-injecting layer.

Preferably, in the first direction, the doping concentration of Mg in the Mg modulation layer is first increased and then decreased, and has a first peak value; and
in the first direction, the doping concentration of Mg in the first hole-injecting layer is first increased and then decreased, and has a second peak value.

More preferably, the first peak value is smaller than the second peak value.

Preferably, in the first direction, the doping concentration of Mg in the Mg modulation layer remains unchanged or fluctuates little within a certain thickness range, and has a plateau value; and
in the first direction, the doping concentration of impurity in the first hole-injecting layer is first increased and then decreased, and has a second peak value.

More preferably, the plateau value is smaller than the second peak value.

Preferably, the second peak value is >1×10²⁰ atom/cm³;
and/or A>1×10¹⁹ atom/cm³;
and/or C>5×10¹⁸ atom/cm³.

Preferably, the multi-quantum well light-emitting layer includes an element In; and
in the first direction, a concentration of In has a characteristic of fluctuation, and the fluctuation of a concentration value of In includes several peaks and several valleys.

Preferably, a linear distance between the peak of the In element nearest to the P-type semiconductor and the second peak value of Mg element is d, where
d≥15 nm; and more preferably, 20 nm≤d≤50 nm.

Preferably, the P-type semiconductor layer includes an element In, and a concentration value of the element In in the P-type semiconductor layer includes at least two peak values of concentration.

Preferably, in the P-type semiconductor layer, a position of a peak value of concentration of the element In coincides with that of the second peak value.

Preferably, the P-type semiconductor layer is of an AlInGaN structure doped with an impurity;
in the Mg modulation layer, a concentration of Al is D;
in the first hole-injecting layer, the concentration of Al is E;
in the electron-blocking layer, the concentration of Al is F; and
in the second hole-injecting layer, the concentration of Al is G, where
F>D>E>G.

Preferably, D>1×10²⁰ atom/cm³.

Preferably, E>1×10²⁰ atom/cm³.

Preferably, F>2×10²⁰ atom/cm³.

Preferably, in the Mg modulation layer, D is first increased and then decreased, and has a third peak value.

The present disclosure further provides a light-emitting diode, including: a substrate; a buffer layer, an N-type semiconductor layer, a multi-quantum well light-emitting layer, a P-type semiconductor layer, and a P-type contact layer which are sequentially stacked on a surface of the substrate; an N electrode provided on a surface of the N-type semiconductor layer; and a P electrode provided on a surface of the P-type semiconductor layer, wherein
the P-type semiconductor layer includes a first electron-blocking layer, a first hole-injecting layer, a second electron-blocking layer and a second hole-injecting layer which are sequentially stacked on a surface of the multi-quantum well light-emitting layer;
an energy level of the first electron-blocking layer is lower than that of the second electron-blocking layer; and
the first electron-blocking layer includes a plurality of sub-layers, wherein at least one sub-layer is a P-type doped nitride layer.

Preferably, the first electron-blocking layer is an Mg modulation layer, an average doping concentration of Mg impurity in the Mg modulation layer is A, an average doping concentration of Mg impurity in the first hole-injecting layer is B, and an average doping concentration of Mg impurity in the second electron-blocking layer is C, where B>A>C.

Preferably, a direction from the second hole-injecting layer to the substrate is defined as a first direction; and
in the first direction, a difference between a maximum value and a minimum value of the doping concentration of Mg in the Mg modulation layer is different from a difference between a maximum value and a minimum value of the doping concentration of Mg in the first hole-injecting layer.

Preferably, in the first direction, the doping concentration of Mg in the Mg modulation layer remains unchanged or fluctuates little within a certain thickness range, and has a plateau value;
in the first direction, the doping concentration of impurity in the first hole-injecting layer is first increased and then decreased, and has a second peak value; and
preferably, the plateau value is smaller than the second peak value.

Preferably, the first electron-blocking layer includes a first sub-layer, a second sub-layer and a third sub-layer which are sequentially provided in a stacking manner;
the first sub-layer includes an aluminum-containing nitride layer and/or an aluminum-free nitride layer;
the second sub-layer includes an aluminum-containing nitride layer and/or an aluminum-free nitride layer; and
the third sub-layer includes an aluminum-containing P-type nitride layer and/or an aluminum-free P-type nitride layer.

Preferably, the aluminum-containing nitride layer includes an AlGaN layer and/or an AlN layer;
preferably, the aluminum-free nitride layer includes a GaN layer;
preferably, the aluminum-containing P-type nitride layer includes a P-type AlGaN layer and/or a P-type AlN layer; and
preferably, the aluminum-free P-type nitride layer includes a P-type GaN layer.

Preferably, a thickness of the first sub-layer is greater than a thickness of the second sub-layer;
and/or the thickness of the second sub-layer is not less than a thickness of the third sub-layer;
and/or a sum of the thickness of the second sub-layer and the thickness of the third sub-layer is less than the thickness of the first sub-layer.

Preferably, the thickness of the first sub-layer is 8-12 nm;
and/or the thickness of the second sub-layer is 1-2 nm;
and/or the thickness of the third sub-layer is 1-2 nm.

Preferably, a thickness of the first hole-injecting layer is greater than a thickness of the Mg modulation layer;
and/or a thickness of the second electron-blocking layer is greater than 10 nm;
and/or a thickness of the second hole-injecting layer is greater than 5 nm.

Compared with the prior art, the present disclosure has the following beneficial effects:
(1) For the epitaxial structure of a light-emitting diode provided by the present disclosure, in this epitaxial structure, the Mg modulation layer is included as transition between the multi-quantum well light-emitting layer and the first hole-injecting layer, and the concentration of Mg in the Mg modulation layer is between that in the multi-quantum well light-emitting layer and that in the first hole-injecting layer, thus having good electron-blocking and hole-injecting effects.
(2) In the epitaxial structure of a light-emitting diode provided by the present disclosure, there is correspondingly a peak value of Al in the Mg modulation layer, and Al having a maximum value can generate a better electron-blocking effect.
(3) For the light-emitting diode provided by the present disclosure, the light-emitting diode has better electron-blocking effect and better hole-injecting effect, and thus has better luminous efficacy.

### BRIEF DESCRIPTION OF DRAWINGS

In order to more clearly illustrate technical solutions in embodiments of the present disclosure or the prior art, drawings which need to be used in the description of the embodiments or the prior art will be briefly introduced below. Apparently, the drawings in the following description are merely for some embodiments of the present disclosure, and those ordinarily skilled in the art still could obtain other drawings in light of these drawings, without using inventive efforts.

FIG. 1 is a schematic view of an epitaxial structure of a light-emitting diode provided in an embodiment of the present disclosure.

FIG. 2 is a chart of results of SIMS detection of the epitaxial structure of a light-emitting diode provided in an embodiment of the present disclosure.

FIG. 3 is a chart of results of SIMS detection of the epitaxial structure of a light-emitting diode provided in another embodiment of the present disclosure.

FIG. 4 is a schematic view of a structure of the light-emitting diode provided by the present disclosure.

FIG. 5 is a schematic view of another structure of the light-emitting diode provided by the present disclosure.

FIG. 6 is a partial structural schematic view of still another structure of the light-emitting diode provided by the present disclosure.

### REFERENCE SIGNS

10, 110—substrate;
20, 120—buffer layer;
30, 130—N-type semiconductor layer;
40, 140—multi-quantum well light-emitting layer;
300, 150—P-type semiconductor layer;
151—Mg modulation layer;
80—first electron-blocking layer;
81—first sub-layer;
82—second sub-layer;
83—third sub-layer;
90, 152—first hole-injecting layer;
153—electron-blocking layer;
50—second electron-blocking layer;
60, 154—second hole-injecting layer;
70—P-type contact layer;
100—N electrode;
200—P electrode.

### DETAILED DESCRIPTION OF EMBODIMENTS

Technical solutions of the present disclosure will be described clearly and completely below in conjunction with the drawings and embodiments, while those skilled in the art would understand that only some but not all embodiments of the present disclosure are described below, and they are merely used for illustrating the present disclosure, but should not be considered as limiting the scope of the present disclosure. All of other embodiments obtained by those ordinarily skilled in the art based on the embodiments in the present disclosure without using inventive efforts shall fall within the scope of protection of the present disclosure. Embodiments, for which no specific conditions are specified, are performed according to conventional conditions or conditions recommended by the manufactures. Where manufacturers of reagents or apparatuses used are not specified, they are conventional products commercially available.

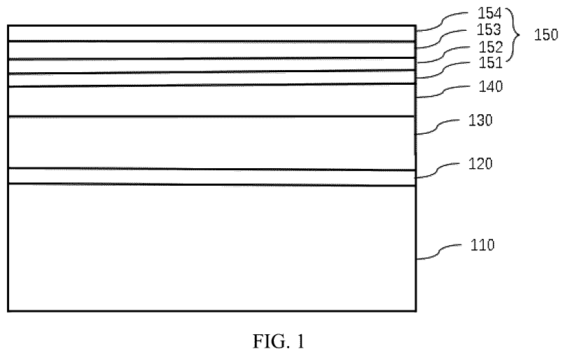

An epitaxial structure of a light-emitting diode provided by the present disclosure, as shown in FIG. 1, includes a substrate 110, and an N-type semiconductor layer 130, a multi-quantum well light-emitting layer 140, and a P-type semiconductor layer 150 which are sequentially provided on an upper surface of the substrate 110, wherein the P-type semiconductor layer 150 includes a first hole-injecting layer 152, an electron-blocking layer 153 and a second hole-injecting layer 154, the P-type semiconductor layer 150 is doped therein with a P-type impurity Mg, and the P-type impurity Mg has different doping concentrations or concentration variations in different sub-layers of the P-type semiconductor layer 150.

An Mg modulation layer 151 is provided between the multi-quantum well light-emitting layer 140 and the first hole-injecting layer 152; and

An average doping concentration of impurity in the Mg modulation layer 151 is A, an average doping concentration of impurity in the first hole-injecting layer 152 is B, and an average doping concentration of impurity in the electron-blocking layer 153 is C, where B>A>C.

For the epitaxial structure of a light-emitting diode provided by the present disclosure, in this epitaxial structure, the Mg modulation layer 151 is included as transition between the multi-quantum well light-emitting layer 140 and the first hole-injecting layer 152, and the concentration of Mg in the Mg modulation layer 151 is between that in the multi-quantum well light-emitting layer 140 and the first hole-injecting layer 152, thus having good effects of blocking electrons and injecting holes.

In a preferred embodiment, a direction from the second hole-injecting layer 154 to the substrate 110 is defined as a first direction; and

In the first direction, a variation magnitude of the doping concentration of Mg in the Mg modulation layer 151 is different from a variation magnitude of the doping concentration of Mg in the first hole-injecting layer 152, that is, a difference between a maximum value and a minimum value of the doping concentration of Mg in the Mg modulation layer 151 is different from a difference between a maximum value and a minimum value of the doping concentration of Mg in the first hole-injecting layer 152.

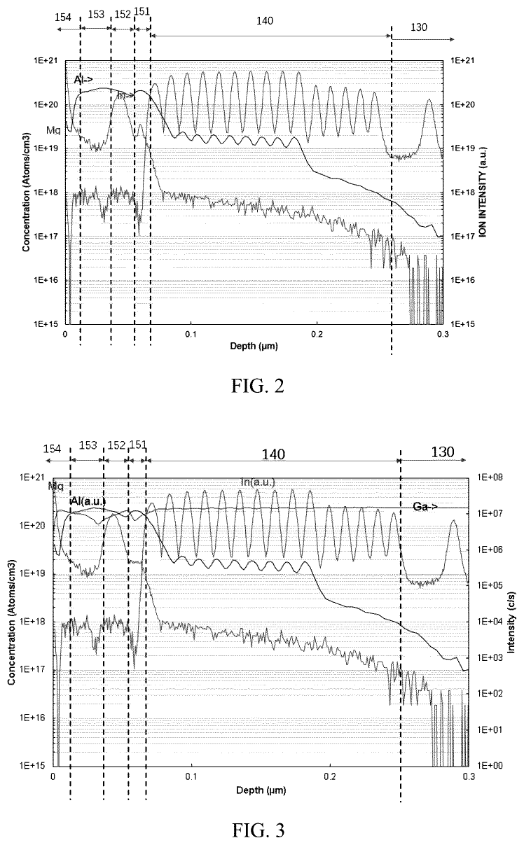

FIG. 2 is a chart of results of SIMS detection of the epitaxial structure of a light-emitting diode provided by embodiments of the present disclosure. In a preferred embodiment, as shown in FIG. 2, in the first direction, the doping concentration of Mg in the Mg modulation layer 151 is first increased and then decreased, and has a first peak value; and
in the first direction, the doping concentration of Mg in the first hole-injecting layer 152 is first increased and then decreased, and has a second peak value.

In a preferred embodiment, the first peak value is smaller than the second peak value.

FIG. 3 is a chart of results of SIMS detection of the epitaxial structure of a light-emitting diode provided by another embodiment of the present disclosure. In a preferred embodiment, as shown in FIG. 3, in the first direction, the doping concentration of Mg in the Mg modulation layer 151 remains unchanged or fluctuates little within a certain thickness range, and has a plateau value, wherein the certain thickness range is within a certain thickness interval not exceeding a thickness of the Mg modulation layer 151; and
in the first direction, the doping concentration of impurity in the first hole-injecting layer 152 is first increased and then decreased, and has a second peak value.

In a preferred embodiment, the plateau value is smaller than the second peak value.

In a preferred embodiment, the second peak value is >1×10²⁰ atom/cm³;
and/or A>1×10¹⁹ atom/cm³;
and/or C>5×10¹⁸ atom/cm³.

In a preferred embodiment, the multi-quantum well light-emitting layer 140 includes an element In; and
in the first direction, a concentration of In has a characteristic of fluctuation, and as shown in FIG. 2, the fluctuation of a concentration value of In includes several peaks and several valleys.

In a preferred embodiment, a linear distance between the peak nearest to the P-type semiconductor and the second peak value is d; and
d≥15 nm; and more preferably, 20 nm≤d≤50 nm.

In a preferred embodiment, the P-type semiconductor layer 150 includes an element In, and a concentration of the element In in the P-type semiconductor layer 150 includes at least two peak values of the concentration.

In a preferred embodiment, in the P-type semiconductor layer 150, a position of a peak value of concentration of the element In coincides with that of the second peak value.

A concentration ratio of Mg/In affects the effect of injecting holes, and can achieve better luminous efficacy.

In a preferred embodiment, the P-type semiconductor layer 150 is of an AlInGaN structure doped with an impurity;

In the Mg modulation layer 151, a concentration of Al is D;

In the first hole-injecting layer 152, the concentration of Al is E;

In the electron-blocking layer 153, the concentration of Al is F;

In the second hole-injecting layer 154, the concentration of Al is G; and

F>D>E>G.

In a preferred embodiment, D>1×10²⁰ atom/cm³.

In a preferred embodiment, E>1×10²⁰ atom/cm³.

In a preferred embodiment, F>2×10²⁰ atom/cm³.

In a preferred embodiment, in the Mg modulation layer 151, D is first increased and then decreased, and has a third peak value. There is correspondingly a peak value of Al in the Mg modulation layer, and Al having a maximum value can generate a better electron-blocking effect.

In addition, the concentration of Al has a good effect of limiting carrier overflow, and cooperates with the concentration of Mg/In to obtain better luminous efficacy of the diode.

An embodiment of the present disclosure provides a preparation method for the epitaxial structure of a light-emitting diode, including the following steps:
(1) providing a substrate 110, such as a sapphire substrate 110, and purging the sapphire substrate 110 at a high temperature;
(2) growing a buffer layer 120 on the sapphire substrate;
(3) growing an undoped GaN layer on the buffer layer 120;
(4) growing an n-type doped GaN layer on the undoped GaN layer;
(5) growing a multi-quantum well light-emitting layer 140 on the n-type doped GaN layer; and
(6) growing an Mg modulation layer 151, a first hole-injecting layer 152, an electron-blocking layer 153, and a second hole-injecting layer 154 sequentially on the multi-quantum well light-emitting layer 140.

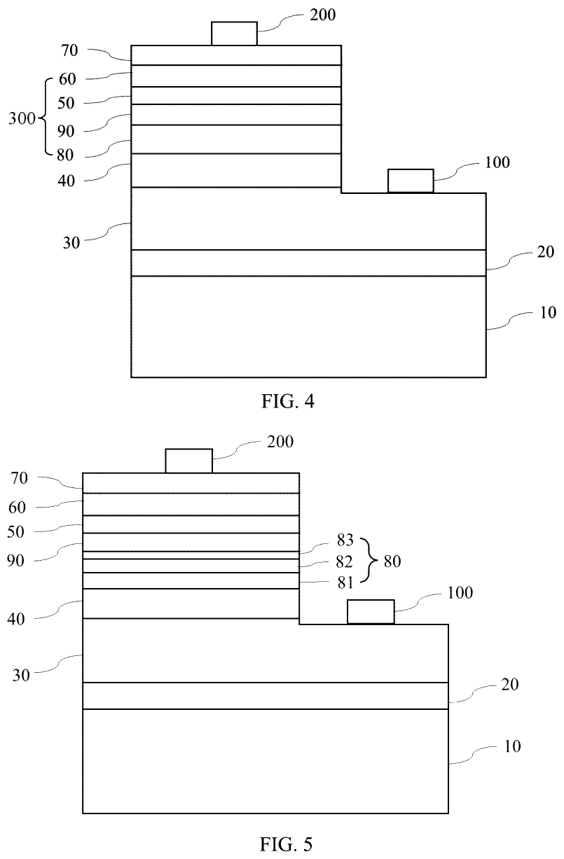

The present disclosure further provides a light-emitting diode. As shown in FIG. 4, the light-emitting diode includes a substrate 10; a buffer layer 20, an N-type semiconductor layer 30, a multi-quantum well light-emitting layer 40, a P-type semiconductor layer 300, and a P-type contact layer 70 which are sequentially stacked on the substrate 10; an N electrode 100 provided on a surface of the N-type semiconductor layer 30; and a P electrode 200 provided on a surface of the P-type semiconductor layer 300.

The P-type semiconductor layer 300 includes a first electron-blocking layer 80, a first hole-injecting layer 90, a second electron-blocking layer 50 and a second hole-injecting layer 60 which are sequentially stacked on a surface of the multi-quantum well light-emitting layer 40.

The first electron-blocking layer 80 and the second electron-blocking layer 50 each contain an aluminum element, and a content of the aluminum element in the first electron-blocking layer 80 is lower than a content of the aluminum element in the second electron-blocking layer 50.

Further, the first electron-blocking layer 80 is an Mg modulation layer doped with Mg, an average doping concentration of Mg impurity in the Mg modulation layer is A, an average doping concentration of Mg impurity in the first hole-injecting layer is B, and an average doping concentration of Mg impurity in the second electron-blocking layer is C, where B>A>C.

If a direction from the second hole-injecting layer to the substrate is defined as a first direction, then in the first direction, a difference between a maximum value and a minimum value of the doping concentration of Mg in the Mg modulation layer is different from a difference between a maximum value and a minimum value of the doping concentration of Mg in the first hole-injecting layer. Preferably, in the first direction, the doping concentration of Mg in the Mg modulation layer remains unchanged or fluctuates little in a certain thickness range, and has a plateau value; in the first direction, the doping concentration of impurity in the first hole-injecting layer is first increased and then decreased, and has a second peak value; and the plateau value is smaller than the second peak value.

In another embodiment, as shown in FIG. 5, the first electron-blocking layer 80 includes a first sub-layer 81, a second sub-layer 82 and a third sub-layer 83 which are sequentially stacked. Further, the first sub-layer 81 includes an aluminum-containing nitride layer and/or an aluminum-free nitride layer; the second sub-layer 82 includes an aluminum-containing nitride layer and/or an aluminum-free nitride layer; and the third sub-layer 83 includes an aluminum-containing P-type nitride layer and/or an aluminum-free P-type nitride layer. Preferably, the aluminum-containing nitride layer includes an AlGaN layer and/or an AlN layer; the aluminum-free nitride layer includes a GaN layer; the aluminum-containing P-type nitride layer includes a P-type AlGaN layer and/or a P-type AlN layer; and the aluminum-free P-type nitride layer includes a P-type GaN layer.

30% and more of a thickness of the first electron-blocking layer 80 is an Al-containing nitride, for example, the first sub-layer 81 is an AlGaN layer, the second sub-layer 82 is an AlN layer, and the third sub-layer 83 is a P-type AlN layer.

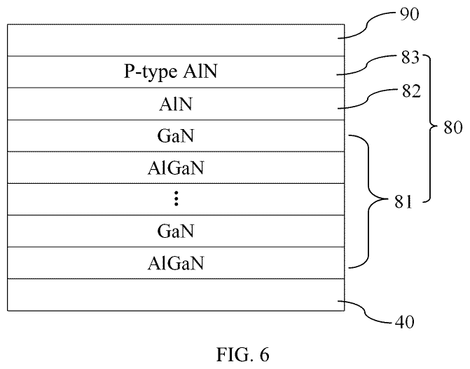

In some specific embodiments of the present disclosure, the first sub-layer 81 includes superlattice structure layers. An alternating period of the superlattice structure layers is 2-8 periods, and 3 periods, 4 periods, 5 periods, 6 periods or 7 periods can also be selected. Preferably, the superlattice structure layers include AlGaN layers and GaN layers which are stacked periodically and alternately. As shown in FIG. 6, a first sub-layer 81, a second sub-layer 82 and a third sub-layer 83 are sequentially stacked on a surface of the multi-quantum well light-emitting layer 40, and the first sub-layer 81 in the first electron-blocking layer 80 is an AlGaN/GaN superlattice structure layer, the second sub-layer 82 is an AlN layer, and the third sub-layer 83 is a P-type AlN layer.

Generally, a thickness of the first sub-layer 81 is greater than that of the second sub-layer 82; the thickness of the second sub-layer 82 is not less than that of the third sub-layer, a sum of thicknesses of the second sub-layer 82 and the third sub-layer 83 is less than that of the first sub-layer 81, and the thickness of the third sub-layer 83 is less than 20% of that of the first electron-blocking layer 80. Specifically, the thickness of the first sub-layer 81 is 8-12 nm; the thickness of the second sub-layer 82 is 1-2 nm; and the thickness of the third sub-layer 83 is 1-2 nm.

The first hole-injecting layer 90 includes a low-temperature P-type AlInGaN layer. Preferably, a P-type impurity used in the low-temperature P-type AlInGaN layer is Mg, a doping concentration is not more than 1×10²⁰ atom/cm³, or it may also be 3×10²⁰ atom/cm³, 5×10²⁰ atom/cm³, 8×10²⁰ atom/cm³ or 1×10²¹ atom/cm³. A content of the aluminum element in the first hole-injecting layer 90 is smaller than a content of the aluminum element in the first electron-blocking layer 80. But a thickness of the first hole-injecting layer 90 is greater than that of the first electron-blocking layer 80.

The second hole-injecting layer 60 includes a high-temperature P-type GaN layer. Preferably, the P-type impurity doped in the high-temperature P type GaN layer is Mg, a doping concentration of the P-type impurity is more than 3×10¹⁹ atom/cm³, or it may also be 5×10¹⁹ atom/cm³, 8×10¹⁹ atom/cm³, 1×10²⁰ atom/cm³, 5×10²⁰ atom/cm³ or 8×10²¹ atom/cm³.

The second electron-blocking layer 50 includes one of an AlGaN layer and a P-type AlGaN layer. A thickness of the second electron-blocking layer 50 is greater than 10 nm, preferably 10-100 nm (or it may also be 15 nm, 20 nm, 25 nm, 30 nm, 35 nm, 40 nm, 50 nm, 60 nm, 70 nm, 80 nm, 90 nm or 95 nm); a thickness of the second hole-injecting layer 60 is greater than 5 nm, preferably 5-100 nm (or it may also be 10 nm, 15 nm, 20 nm, 25 nm, 30 nm, 35 nm, 40 nm, 50 nm, 60 nm, 70 nm, 80 nm, 90 nm or 95 nm).

In some specific embodiments of the present disclosure, a material of the substrate 10 includes at least one of sapphire, silicon carbide and silicon substrate.

In some specific embodiments of the present disclosure, the buffer layer 20 includes an AlN buffer layer 20 and/or a GaN buffer layer 20.

In some specific embodiments of the present disclosure, the N-type semiconductor layer 30 includes an N-type GaN layer doped with Si.

In some specific embodiments of the present disclosure, the multi-quantum well light-emitting layer 40 includes an InGaN potential-well layer and a GaN potential-barrier layer provided in a stacking manner. Preferably, the multi-quantum well light-emitting layer 40 is of an InGaN/GaN superlattice structure, and the first electron-blocking layer 80 is provided on the InGaN potential-well layer, which is equivalent to the last InGaN potential-well layer of the multi-quantum well light-emitting layer 40.

In some specific embodiments of the present disclosure, the P-type contact layer 70 includes a P-type GaN layer. Preferably, the P-type impurity doped in the P-type contact layer 70 is Mg. More preferably, a doping concentration of Mg in the P-type contact layer 70 is greater than the doping concentration of Mg in the second hole-injecting layer 60 (the high-temperature P-type GaN layer), and the doping concentration of Mg in the P-type contact layer 70 is less than the doping concentration of Mg in the first hole-injecting layer 90 (the low-temperature P-type AlInGaN layer).

Although the present disclosure has been illustrated and described with specific embodiments, it should be realized that various embodiments above are merely used for illustrating the technical solutions of the present disclosure, rather than limiting the present disclosure; those ordinarily skilled in the art should understand that, without departing from the spirit and scope of the present disclosure, the technical solutions disclosed in various preceding embodiments could be modified, or equivalent substitutions could be made to some or all of the technical features therein; and these modifications or substitutions do not make corresponding technical solutions essentially depart from the scope of the technical solutions of various embodiments of the present disclosure; therefore, it means that the attached claims cover all of these substitutions and modifications within the scope of the present disclosure.

1. An epitaxial structure of a light-emitting diode, comprising: a substrate; and
an N-type semiconductor layer, a multi-quantum well light-emitting layer, and a P-type semiconductor layer which are sequentially provided on an upper surface of the substrate, wherein the P-type semiconductor layer comprises a first hole-injecting layer, an electron-blocking layer and a second hole-injecting layer, wherein the P-type semiconductor layer is doped therein with a P-type impurity Mg, and the P-type impurity Mg has different doping concentrations or concentration variations in different sub-layers of the P-type semiconductor layer;
an Mg modulation layer is provided between the multi-quantum well light-emitting layer and the first hole-injecting layer;
an average doping concentration of impurity in the Mg modulation layer is A, an average doping concentration of impurity in the first hole-injecting layer is B, and an average doping concentration of impurity in the electron-blocking layer is C, where
B>A>C.

2. The epitaxial structure of a light-emitting diode according to claim 1, wherein a direction from the second hole-injecting layer to the substrate is defined as a first direction; and
in the first direction, a difference between a maximum value and a minimum value of the doping concentration of Mg in the Mg modulation layer is different from a difference between a maximum value and a minimum value of the doping concentration of Mg in the first hole-injecting layer.

3. The epitaxial structure of a light-emitting diode according to claim 2, wherein in the first direction, the doping concentration of Mg in the Mg modulation layer is first increased and then decreased, and has a first peak value;
in the first direction, the doping concentration of Mg in the first hole-injecting layer is first increased and then decreased, and has a second peak value; and
the first peak value is smaller than the second peak value.

4. The epitaxial structure of a light-emitting diode according to claim 2, wherein in the first direction, the doping concentration of Mg in the Mg modulation layer remains unchanged or fluctuates little within a certain thickness range, and has a plateau value;
in the first direction, the doping concentration of impurity in the first hole-injecting layer is first increased and then decreased, and has a second peak value; and
the plateau value is smaller than the second peak value.

5. The epitaxial structure of a light-emitting diode according to claim 3, wherein the second peak value is >1×10²⁰ atom/cm³;
and/or A>1×10¹⁹ atom/cm³;
and/or C>5×10¹⁸ atom/cm³.

6. The epitaxial structure of a light-emitting diode according to claim 3, wherein the multi-quantum well light-emitting layer comprises an element In; and
in the first direction, a concentration of In has a characteristic of fluctuation, and the fluctuation of a concentration value of In comprises several peaks and several valleys.

7. The epitaxial structure of a light-emitting diode according to claim 6, wherein a linear distance between the peak of the In element nearest to the P-type semiconductor and the second peak value of Mg element is d, where
d≥15 nm; and
20 nm≤d≤50 nm.

8. The epitaxial structure of a light-emitting diode according to claim 3, wherein the P-type semiconductor layer comprises an element In, and a concentration of the element In in the P-type semiconductor layer comprises at least two peak values of concentration.

9. The epitaxial structure of a light-emitting diode according to claim 8, wherein in the P-type semiconductor layer, a position of a peak value of concentration of the element In coincides with that of the second peak value.

10. The epitaxial structure of a light-emitting diode according to claim 1, wherein
in the Mg modulation layer, a concentration of Al is D;
in the first hole-injecting layer, the concentration of Al is E;
in the electron-blocking layer, the concentration of Al is F;
in the second hole-injecting layer, the concentration of Al is G, where
F>D>E>G;
and/or D>1×10²⁰ atom/cm³;
and/or E>1×10²⁰ atom/cm³; and
and/or F>2×10²⁰ atom/cm³.

11. The epitaxial structure of a light-emitting diode according to claim 10, wherein in the Mg modulation layer, the concentration D of Al is first increased and then decreased, and has a third peak value.

12. A light-emitting diode, comprising: a substrate; a buffer layer, an N-type semiconductor layer, a multi-quantum well light-emitting layer, a P-type semiconductor layer, and a P-type contact layer which are sequentially stacked on a surface of the substrate; an N electrode provided on a surface of the N-type semiconductor layer; and a P electrode provided on a surface of the P-type semiconductor layer, wherein
the P-type semiconductor layer comprises a first electron-blocking layer, a first hole-injecting layer, a second electron-blocking layer and a second hole-injecting layer which are sequentially stacked on a surface of the multi-quantum well light-emitting layer;
an energy level of the first electron-blocking layer is lower than that of the second electron-blocking layer; and
the first electron-blocking layer comprises a plurality of sub-layers, wherein at least one sub-layer is a P-type doped nitride layer.

13. The light-emitting diode according to claim 12, wherein the first electron-blocking layer is an Mg modulation layer, an average doping concentration of Mg impurity in the Mg modulation layer is A, an average doping concentration of Mg impurity in the first hole-injecting layer is B, and an average doping concentration of Mg impurity in the second electron-blocking layer is C, where B>A>C.

14. The light-emitting diode according to claim 13, wherein a direction from the second hole-injecting layer to the substrate is defined as a first direction; and
in the first direction, a difference between a maximum value and a minimum value of the doping concentration of Mg in the Mg modulation layer is different from a difference between a maximum value and a minimum value of the doping concentration of Mg in the first hole-injecting layer.

15. The light-emitting diode according to claim 14, wherein in the first direction, the doping concentration of Mg in the Mg modulation layer remains unchanged or fluctuates little within a certain thickness range, and has a plateau value;
in the first direction, the doping concentration of impurity in the first hole-injecting layer is first increased and then decreased, and has a second peak value; and
the plateau value is smaller than the second peak value.

16. The light-emitting diode according to claim 13, wherein the first electron-blocking layer comprises a first sub-layer, a second sub-layer and a third sub-layer which are sequentially provided in a stacking manner;
the first sub-layer comprises an aluminum-containing nitride layer and/or an aluminum-free nitride layer;
the second sub-layer comprises an aluminum-containing nitride layer and/or an aluminum-free nitride layer; and
the third sub-layer comprises an aluminum-containing P-type nitride layer and/or an aluminum-free P-type nitride layer.

17. The light-emitting diode according to claim 16, wherein the aluminum-containing nitride layer comprises an AlGaN layer and/or an AlN layer;
the aluminum-free nitride layer comprises a GaN layer;
the aluminum-containing P-type nitride layer comprises a P-type AlGaN layer and/or a P-type AlN layer; and
the aluminum-free P-type nitride layer comprises a P-type GaN layer.

18. The light-emitting diode according to claim 16, wherein a thickness of the first sub-layer is greater than a thickness of the second sub-layer;
and/or the thickness of the second sub-layer is not less than a thickness of the third sub-layer;
and/or a sum of the thickness of the second sub-layer and the thickness of the third sub-layer is less than the thickness of the first sub-layer.

19. The light-emitting diode according to claim 18, wherein the thickness of the first sub-layer is 8-12 nm;
and/or the thickness of the second sub-layer is 1-2 nm;
and/or the thickness of the third sub-layer is 1-2 nm.

20. The light-emitting diode according to claim 13, wherein a thickness of the first hole-injecting layer is greater than a thickness of the Mg modulation layer;
and/or a thickness of the second electron-blocking layer is greater than 10 nm;
and/or a thickness of the second hole-injecting layer is greater than 5 nm.
